(19) United States
(12) Patent Application Publication
(10) Pub. No.: US 2009/0179307 A1
(43) Pub. Date: Jul. 16, 2009

(54) INTEGRATED CIRCUIT SYSTEM EMPLOYING FEED-FORWARD CONTROL

(75) Inventors: Wenzhan Zhou, Singapore (SG); Jasper Goh, Singapore (SG); Hui Peng Koh, Singapore (SG); Jung Yu Hsieh, Singapore (SG); Meisheng Zhou, Singapore (SG)

Correspondence Address: LAW OFFICES OF MIKIO ISHIMARU, 333 W. EL CAMINO REAL, SUITE 330, SUNNYVALE, CA, 94087, US

(73) Assignee: CHARTERED SEMICONDUCTOR MANUFACTURING LTD., Singapore (SG)

(21) Appl. No.: 12/014,448

(22) Filed: Jan. 15, 2008

(51) Int. Cl. H01L 23/58; H01L 21/66

(52) U.S. Cl. 257/632; 438/8; 257/E23.002; 257/E21.53

(57) ABSTRACT

An integrated circuit system that includes: providing a substrate and a material layer; measuring a parameter of the material layer; and correlating the thickness of an anti-reflective layer to the measured parameter of the material layer for critical dimension control.

### TECHNICAL FIELD

The present invention relates generally to integrated circuits, and more particularly to an integrated circuit system employing feed-forward control.

### BACKGROUND ART

Integrated circuits find application in many of today's consumer electronics, such as cell phones, video cameras, portable music players, printers, computers, etc. Integrated circuits may include a combination of active devices, passive devices and their interconnections.

As the technology node of integrated circuits continues to decrease, manufacturers have been forced to create higher precision features by achieving better line-width control. The minimum line-width that can be fabricated for the integrated circuit is commonly referred to as the critical dimension (CD). Arguably, photolithography is the most important operation in the development of an integrated circuit and CD control is the critical parameter within photolithography. Unfortunately, CD control within a photolithography process is not easily achieved and commonly employed feedback systems between a stepper and a CD metrology tool are often ineffective due to etch bias errors.

One of the major difficulties associated with CD control of a photolithography process is the reflection of light from a surface underneath the photoresist material. This reflected light causes exposure problems within the photoresist material, which can result in process latitude and control problems. For example, angular reflections can cause notching of the CD feature and exposure of photoresist material outside of the CD defined by the photoresist mask. Additionally, standing wave effects can also cause non-uniform exposure along the thickness of the photoresist material, as well.

Consequently, manufacturers of integrated circuits have employed anti-reflective coatings, applied directly to the reflective surfaces, to reduce the deleterious effects that reflected light can have on CD control. Unfortunately, as the industry transitions to shorter wavelength light (e.g. −157 nanometer and below) to create smaller CD features, the light reflected from surfaces below the anti-reflective coatings increases and traditional anti-reflective coating approaches, which commonly employ statistical process control methods, are unable to meet the tight process control requirements of sub-65 nanometer technology.

Thus, a need still remains for a reliable integrated circuit system and method of fabrication, wherein the integrated circuit system exhibits enhanced CD control for a sub-65 nanometer photolithography process. In view of the ever-increasing commercial competitive pressures, increasing consumer expectations, and diminishing opportunities for meaningful product differentiation in the marketplace, it is increasingly critical that answers be found to these problems. Moreover, the ever-increasing need to save costs, improve efficiencies, and meet such competitive pressures adds even greater urgency to the critical necessity that answers be found to these problems.

Solutions to these problems have been long sought but prior developments have not taught or suggested any solutions and, thus, solutions to these problems have long eluded those skilled in the art.

### DISCLOSURE OF THE INVENTION

The present invention provides an integrated circuit system including: providing a substrate and a material layer; measuring a parameter of the material layer; and correlating the thickness of an anti-reflective layer to the measured parameter of the material layer for critical dimension control.

Certain embodiments of the invention have other aspects in addition to or in place of those mentioned above. The aspects will become apparent to those skilled in the art from a reading of the following detailed description when taken with reference to the accompanying drawings.

### BRIEF DESCRIPTION OF THE DRAWINGS

FIG. 1 is a cross-sectional view of an integrated circuit system in an initial stage of manufacture in accordance with an embodiment of the present invention;

FIG. 2 is the structure of FIG. 1 during measurement;

FIG. 3 is the structure of FIG. 2 after deposition of an anti-reflective layer;

FIG. 4 is the structure of FIG. 3 after developing a photoresist material;

FIG. 5 is the structure of FIG. 4 during measurement;

FIG. 6 is a cross-sectional view of an integrated circuit system in accordance with another embodiment of the present invention; and

FIG. 7 is a flow chart of an integrated circuit system for an integrated circuit system, in accordance with an embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that process or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail.

Likewise, the drawings showing embodiments of the system are semi-diagrammatic and not to scale and, particularly, some of the dimensions are for the clarity of presentation and are shown exaggerated in the drawing FIGs. Additionally, where multiple embodiments are disclosed and described having some features in common, for clarity and ease of illustration, description, and comprehension thereof, similar and like features one to another will ordinarily be described with like reference numerals.

The term “horizontal” as used herein is defined as a plane parallel to the conventional plane or surface of the substrate, regardless of its orientation. The term “vertical” refers to a direction perpendicular to the horizontal as just defined. Terms, such as “on”, “above”, “below”, “bottom”, “top”, “side” (as in “sidewall”), “higher”, “lower”, “upper”, “over”, and “under”, are defined with respect to the horizontal plane.

The term “processing” as used herein includes deposition of material or photoresist, patterning, exposure, development, etching, cleaning, and/or removal of the material or photoresist as required in forming a described structure.

The term “on” is used herein to mean there is direct contact among elements.

The terms “example” or “exemplary” are used herein to mean serving as an instance or illustration. Any aspect or embodiment described herein as an “example” or as “exemplary” is not necessarily to be construed as preferred or advantageous over other aspects or designs.

The term “system” as used herein means and refers to the method and to the apparatus of the present invention in accordance with the context in which the term is used.

It will be appreciated by one of ordinary skill in the art that a track tool can generally coat a wafer with a photosensitive material, bake the wafer, and develop a pattern on the wafer. Moreover, it will be appreciated by one of ordinary skill in the art that a stepper/scanner tool is generally an optical based system that projects the pattern of a reticle or mask onto an area of a wafer.

Generally, the following embodiment relates to an advanced process control method that minimizes light reflectivity from a surface via a feed-forward process and/or a feedback process, thereby improving after development inspection CD control. By way of example, minimization of light reflectivity from a surface can be achieved by utilizing feed-forward control to manipulate subsequent process parameters by correlating previously measured data to an optimum anti-reflective coating thickness.

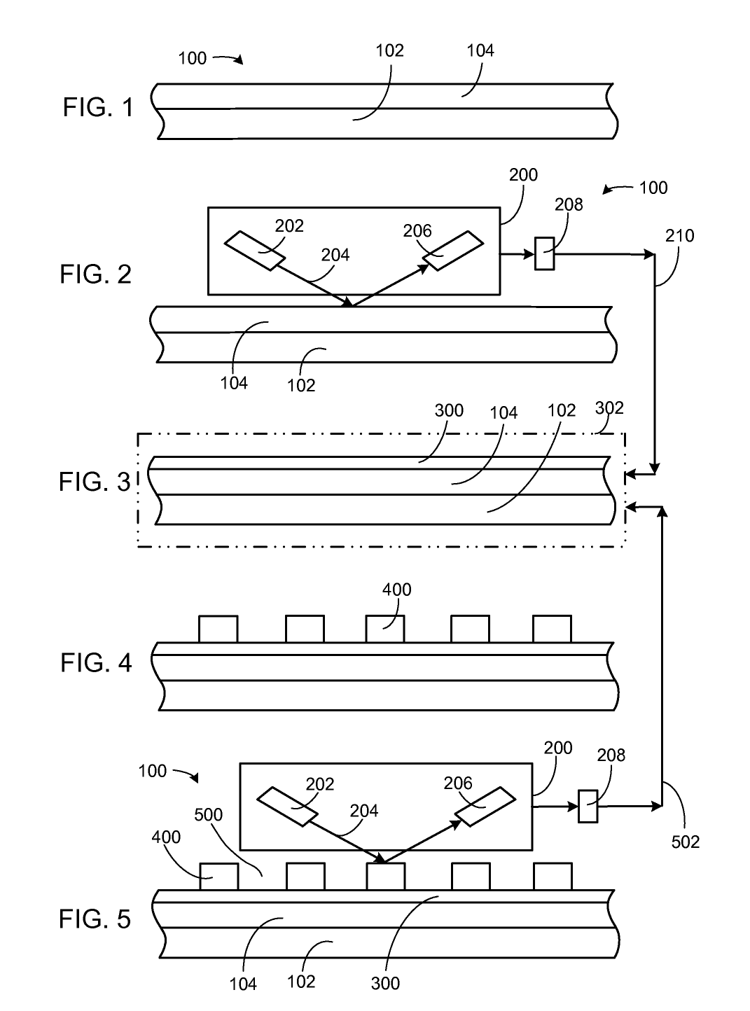

FIGS. 1-5, which follow, depict by way of example and not by limitation, an exemplary process flow for the formation of an integrated circuit system and they are not to be construed as limiting. It is to be understood that a plurality of conventional processes that are well known within the art and not repeated herein, may precede or follow FIGS. 1-5. Moreover, it is to be understood that many modifications, additions, and/or omissions may be made to the below described process without departing from the scope or spirit of the claimed subject matter. For example, the below described process may include more, fewer, or other steps.

Additionally, it is to be appreciated that the integrated circuit system of the present disclosure may include any number of active devices (e.g., a multi-electrode device in which the current flowing between two specified electrodes is controlled or modulated by the voltage applied at a control electrode) and/or passive devices and their interconnections. Furthermore, it is to be understood that one or more of the integrated circuit system could be prepared at one time on a medium, which could be separated into individual or multiple integrated circuit assemblies at a later stage of fabrication.

Referring now to FIG. 1, therein is shown a partial cross-sectional view of an integrated circuit system 100 in an initial stage of manufacture in accordance with an embodiment of the present invention. The integrated circuit system 100 may include a substrate 102, such as a two hundred (200) mm or three hundred (300) mm semiconductor wafer upon which any number of active and/or passive device structures and their interconnections could be formed. By way of example, the substrate 102 may include any semiconducting material, such as, Si, SiC, SiGe, Si/SiGe, SiGeC, Ge, GaAs, InAs, InP, other III/V or II/VI compound semiconductors, as well as silicon-on-insulator configurations. Additionally, the substrate 102 may also include doped and undoped configurations, epitaxial layers, strained configurations, and one or more crystalline orientations (e.g. —<100>, <110>, and/or <111> orientations), which may be strategically employed to optimize carrier mobility within nFET and pFET devices.

However, the examples provided for the substrate 102 are not to be construed as limiting and the composition of the substrate 102 may include any material or configuration that physically and electrically enables the formation of active and/or passive device structures and their interconnections.

A material layer 104 can be formed over or on the substrate 102. By way of example, the material layer 104 may include one or more layers of a conducting material, a semiconducting material, a dielectric material, or a combination thereof. In an aspect of the present embodiment, the material layer 104 may include a silicon dioxide layer with a thickness ranging from about ten (10) nanometers to about two hundred (200) nanometers, for example.

Referring now to FIG. 2, therein is shown the structure of FIG. 1 during measurement. As is well known within the art, step changes and drift within a fabrication process can introduce significant process variability, thereby adversely impacting overall product yield. For example, after several process runs, the thickness of a layer may fluctuate due to the build-up of contaminants on the walls of a deposition chamber. Consequently, a subsequent layer that has been optimized to the previous layers theoretical thickness will no longer be optimized when that previous layer drifts from its theoretical thickness.

Accordingly, the present inventors have discovered that by measuring the material layer 104 and/or the substrate 102 that these actual measurements can be utilized to optimize subsequent process steps. In an aspect of the present embodiment, after forming the material layer 104, the integrated circuit system 100 can be sent to a measurement system for measuring. As an exemplary illustration, a metrology tool 200, which includes an energy source 202, an energy beam 204, and a detector 206, can be used to measure the material layer 104 and/or the substrate 102 via a non-destructive, non-contact optical measurement technique, such as ellipsometry, spectroscopic ellipsometry, and/or reflection spectroscopy. However, it is to be understood that the metrology tool 200 may utilize any measurement technique, whether in situ or ex situ of the integrated circuit system 100 fabrication process, that provides a parameter or data such as the thickness, index of refraction, and/or profile of the material layer 104 and/or the substrate 102.

In an aspect of the present embodiment, the metrology tool 200 can be used to measure the thickness of the material layer 104. It is to be understood that the measured thickness of the material layer 104 may include data for the thickness of the material layer 104 as a whole and/or data for the thickness of each layer within the material layer 104.

The thickness measurement of the material layer 104 is then sent as input data to a processing unit 208 from the metrology tool 200, wherein a program or software stored and executed within the processing unit 208 can process the input data. By way of example, the program or software of the processing unit 208 can convert the measured thickness of the material layer 104 to a suggested thickness for a subsequently formed layer from previously correlated data that is known to minimize the energy reflection or light reflectivity from the material layer 104 and/or the substrate 102, thereby improving CD control.

The output data of the processing unit 208 (e.g., the suggested thickness for a subsequently formed layer that is known to minimize the energy reflection or light reflectivity from the material layer 104 and/or the substrate 102) is then fed-forward to a subsequent process step, via a feed-forward loop 210. The subsequent process step can then utilize the data provided by the feed-forward loop 210 to improve the CD control of the integrated circuit system 100. By way of example, the processing unit 208 may include a computer integrated manufacturing software package that allows the processing unit 208 to output data to, control and/or operate a track tool via the feed-forward loop 210.

Referring now to FIG. 3, therein is shown the structure of FIG. 2 after deposition of an anti-reflective layer 300. In an aspect of the present embodiment, after measuring the material layer 104 and/or the substrate 102, the integrated circuit system 100 can be sent to a manufacturing system 302 (shown in phantom outline) including a track tool (not shown) and a stepper/scanner tool (not shown). By way of example, the anti-reflective layer 300 and a photoresist material 400, of FIG. 4, can be deposited within the track tool and the photoresist material 400 can be exposed within the stepper/scanner tool. It is to be understood that the anti-reflective layer 300 can be deposited over or on the material layer 104 and that the photoresist material 400 can be deposited over or on the anti-reflective layer 300.

Notably, the track tool can receive the output data from the processing unit 208 via the feed-forward loop 210, both of FIG. 2, and use this information to set the deposition parameters to form the anti-reflective layer 300 with a thickness that reduces reflections and improves CD control, for example. It is to be understood that the thickness of the anti-reflective layer 300 is determined by correlating (e.g., empirically) a measured parameter of the material layer 104 and/or the substrate 102 to a property or parameter (e.g., thickness) of the anti-reflective layer 300 that will minimize reflectivity from the underlying layers, thereby improving CD control.

Generally, the thickness of the anti-reflective layer 300 can be tuned to a measured parameter (e.g., thickness) of the material layer 104 and/or the substrate 102, thereby minimizing reflectivity from underlying layers and improving CD control. This type of feed-forward process, which can utilize, for example, the thickness of the material layer 104 as a basis or reference for determining the optimum thickness for the anti-reflective layer 300, can reduce reflectivity by up to about ninety (90) percent. By way of example, the thickness of the anti-reflective layer 300 can be adjusted by varying the viscosity of the anti-reflective layer 300 or by altering the spin speed of the spin coating equipment used to form the anti-reflective layer 300.

It is important to note that the feed-forward process discovered by the present inventors also allows additional tuning of the properties of the anti-reflective layer 300 to reduce light reflections. For example, the metrology tool 200, of FIG. 2, could measure data such as the refractive index of the material layer 104 and/or the substrate 102, and feed-forward this information to the anti-reflective layer 300 deposition step, thereby allowing the anti-reflective layer 300 closest to the material layer 104 to have a substantially similar refractive index. Additionally, the anti-reflective layer 300 could be tuned to possess a high absorbency value, k, at a particular wavelength, thereby further minimizing light reflectivity from surfaces formed below the anti-reflective layer 300. Moreover, it is to be understood that the spin speed of the spin coating equipment can also be modulated to tune the thickness of the anti-reflective layer 300.

Additionally, it is important to note that the present embodiment may also employ feedback process control. For, example, the process parameters of the stepper/scanner tool can be adjusted or modified by utilizing information or data provided via a feedback loop 502, of FIG. 5. By way of example, a measurement of the photoresist material 400 can be fed-back to the stepper/scanner tool, via the feedback loop 502, to alter the exposure energy or the focus parameters, thereby improving CD control. However, it is to be understood that the feedback loop 502 is not limited to merely controlling the exposure energy and/or the focus parameters of the stepper/scanner tool. Accordingly, the feedback loop 502 may control any parameter of the stepper/scanner tool that permits improved CD control. The feedback loop 502 employed by the present embodiment will be discussed further in FIG. 5.

As is well known in the art, the anti-reflective layer 300 may include an organic or an inorganic dielectric material that can suppress unintended energy/light reflection from the material layer 104 and/or the substrate 102. The anti-reflective layer 300 may include one or more thin film layers of different material applied in a selected sequence. By way of example, the anti-reflective layer 300 may be a bottom anti-reflective coating.

Moreover, it is to be understood that a release layer could be formed between the material layer 104 and the anti-reflective layer 300 to facilitate removal of the anti-reflective layer 300.

Referring now to FIG. 4, therein is shown the structure of FIG. 3 after developing the photoresist material 400. By way of example, the photoresist material 400 may include an energy sensitive film such as a negative tone resist, a positive tone resist, or a chemically amplified resist that is deposited by techniques well known in the art and not repeated herein. It is to be understood that the photoresist material 400 may include one or more patterned photoresist layers with measured line widths below about 65 nanometers.

As is well known in the art, the photoresist material 400 can be exposed to actinic radiation through a reticle or mask with transparent and opaque regions. The light passing through the transparent regions of the reticle or mask exposes the underlying photoresist layer and depending upon the photoresist layer composition, the exposed portions of the photoresist can either become soluble or insoluble to a subsequent developer.

Referring now to FIG. 5, therein is shown the structure of FIG. 4 during measurement. In an aspect of the present embodiment, after developing the photoresist material 400, the integrated circuit system 100 can be sent to a measurement system, including the metrology tool 200, for measuring. The metrology tool 200 may include the energy source 202, the energy beam 204, and the detector 206. By way of example, the metrology tool 200 may employ non-destructive, non-contact optical measurement techniques such as ellipsometry, spectroscopic ellipsometry or reflection spectroscopy. However, it is to be understood that other measurement techniques may be employed, such as a CD-scanning electron microscope and/or a CD-atomic force microscope.

In an aspect of the present embodiment, the metrology tool 200 could employ spectroscopic ellipsometry to measure the CD of a feature 500, such as an opening with a sub-65 nanometer critical dimension, formed within the photoresist material 400. By way of example, the feature 500 could be used to form a subsequent gate structure, semiconductor island structure, passivation structure, and/or interconnection structure.

However, it is to be understood that the metrology tool 200 may utilize any measurement technique, whether in situ or ex situ of the integrated circuit system 100 fabrication process, that provides a measured parameter or measured data about the photoresist material 400. Examples of such measured parameter or measured data may include CD, sidewall angle, and thickness or height of the photoresist material 400. It is to be understood that the correlation between measured parameters of the photoresist material 400 and the control/process parameters of the stepper/scanner tool can be non-linear and may be handled by nonlinear models.

Notably, the present inventors utilize the measured parameter or the measured data of the current process step via the feedback loop 502 in order to further optimize control parameters of the stepper/scanner tool such as the exposure energy or the focus parameters, to thereby improve CD control. However, it is to be understood that the feedback loop 502 may alter any control/process parameter of the stepper/scanner tool that permits improved CD control.

By way of example, the measured parameter or the measured data of the photoresist material 400 can be sent as input data to the processing unit 208 from the metrology tool 200, wherein a program or software stored and executed within the processing unit 208 can process the input data. The program or software of the processing unit 208 can convert the measured parameter or the measured data of the photoresist material 400 to a suggested control parameter for the stepper/scanner tool, thereby improving CD control.

The result or output data of the processing unit 208 (e.g., the suggested exposure dose or focus range for the stepper/scanner tool) is then fed-back to an earlier process step, via the feedback loop 502. The earlier process step then utilizes the data provided by the feedback loop 502 to improve the CD control of the integrated circuit system 100. By way of example, the processing unit 208 may include a computer integrated manufacturing software package that allows the processing unit 208 to send output data to, control and/or operate a stepper/scanner tool via the feedback loop 502.

It is to be understood that the metrology tool 200 may also be used to measure a parameter, such as the thickness, of the material layer 104 and/or the anti-reflective layer 300 for purposes of reference.

It will be appreciated by those skilled in the art that after forming the feature 500 that the integrated circuit system 100 is now ready for fabrication of electronic devices, which can be strategically designed and formed to implement the desired function of the integrated circuit system 100 (e.g. —sub 65 nanometer CD devices). By way of example, the electronic devices formed within the integrated circuit system 100 may include active components, passive components, processor components, memory components, logic components, digital components, analog components, power components, and so forth, in numerous configurations and arrangements as may be needed.

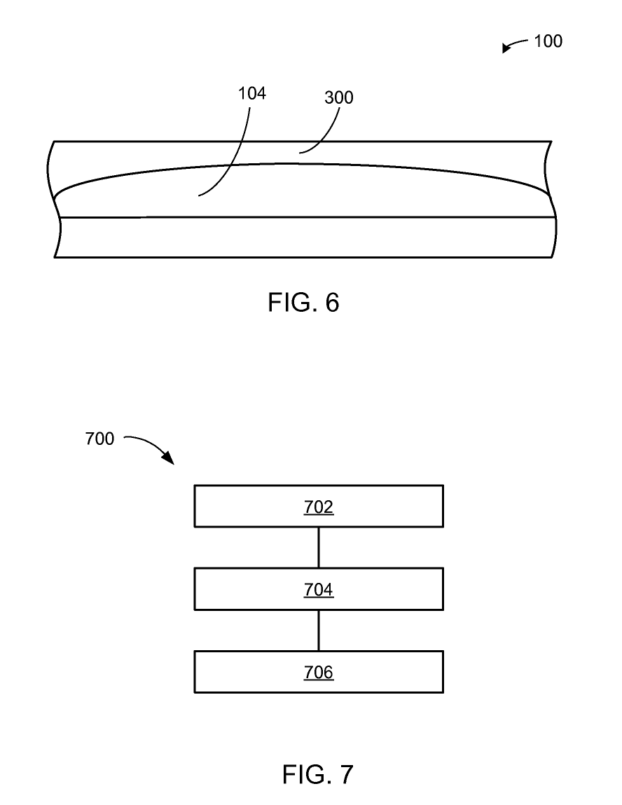

Referring now to FIG. 6, therein is shown a cross-sectional view of the integrated circuit system 100 in accordance with another embodiment of the present invention. It is to be understood that the integrated circuit system 100 of the present embodiment can be substituted for the integrated circuit system 100 employed in FIGS. 1-5.

Generally, the present inventors have discovered that by tuning the spin coating recipe or the chemical vapor deposition (CVD) recipe for the anti-reflective layer 300, it becomes possible to match and/or correlate the material layer 104 thickness profile with the anti-reflective layer 300 thickness profile to minimize the reflectivity from the material layer 104 with a non-uniform thickness.

Per this embodiment, the material layer 104 can possess a non-uniform thickness. For example, the thickness of the material layer 104 may vary from the center to its edge. Notably, the present inventors have discovered that the anti-reflective layer 300 can be specifically tuned to adjust for the thickness variations within the material layer 104. In an aspect of the present embodiment, cast speed, spin speed, and chemical dispense speed can be altered to tune the thickness of the anti-reflective layer 300. However, it is to be understood that the method employed to tune (i.e., impact the thickness uniformity) of the anti-reflective layer 300 can be identified by design of experiment and may not be the same from process to process. In another aspect of the present embodiment, CVD parameters such as temperature, pressure and gas flow rates can be altered to tune the thickness of the anti-reflective layer 300.

By specifically tuning the anti-reflective layer 300 to match the non-uniform thickness of the material layer 104, the energy/light reflectivity throughout the entire thickness range of the material layer 104 can be minimized, thereby improving CD control. In an aspect of the present embodiment, the anti-reflective layer 300 can be tuned by increasing the thickness of the anti-reflective layer 300 where the material layer 104 becomes thinner and by decreasing the thickness of the anti-reflective layer 300 where the material layer 104 becomes thicker. Generally, the anti-reflective layer 300 is tuned to match the material layer 104 based on an optical parameter (i.e., the minimization of light reflectivity from a surface below the anti-reflective layer 300), and that may not provide 1:1 matching (i.e. the thickness of the anti-reflective layer 300 may not match the thickness of the material layer 104).

Additionally, the present embodiment enables an overall reduction in the thickness of the anti-reflective layer 300. Typically, to compensate for thickness variation in the layer below the anti-reflective coating, a second minimum (i.e., the second valley on the swing curve of reflectivity versus anti-reflective layer thickness) thickness is used for an anti-reflective coating. Notably, the present embodiment is able to reduce the thickness of the anti-reflective layer 300 to a first minimum (i.e., the first valley on the swing curve of reflectivity versus anti-reflective layer thickness) when compensating for the thickness variation in the material layer 104, thereby increasing the etch process margin. It is to be understood that etch process margin improves with decreasing thickness of the anti-reflective layer 300 because of reduced photoresist height loss.

Referring now to FIG. 7, therein is shown a flow chart of an integrated circuit system 700 for the integrated circuit system 100, in accordance with an embodiment of the present invention. The integrated circuit system 700 includes providing a substrate and a material layer in a block 702; measuring a parameter of the material layer in a block 704; and correlating the thickness of an anti-reflective layer to the measured parameter of the material layer for critical dimension control in a block 706.

It has been discovered that the present invention thus has numerous aspects. One such aspect is that the present invention improves CD control of a feature. The present invention achieves this objective by employing a feed-forward control process that correlates previously measured data with the thickness of an anti-reflective layer to optimize its anti-reflective properties, thereby improving CD control.

Another aspect of the present invention is that it minimizes the light reflectivity from layers formed below the anti-reflective layer by optimizing the properties of the anti-reflective layer. By way of example, the properties of the anti-reflective layer can be optimized by measuring the parameters of a layer formed beneath the anti-reflective layer and correlating these measured parameters to optimum parameters for the anti-reflective layer that will minimize light reflectivity and improve CD control.

Another aspect of the present invention is that it can correct within material layer reflectivity non-uniformity by tuning the anti-reflective layer to the specific characteristics (e.g., varying thickness) of the material layer beneath the anti-reflective layer, and thus achieve minimized material layer reflectivity throughout the material layer film thickness range.

Another aspect of the present invention is that feed-forward control can manipulate process parameters of subsequent process steps to enable critical dimension uniformity between wafers and wafer lots.

Another aspect of the present invention is that it enables improved critical dimension control by utilizing a feedback process control to alter the exposure energy of a stepper/scanner tool.

Yet another important aspect of the present invention is that it valuably supports and services the historical trend of reducing costs, simplifying systems, and increasing performance.

These and other valuable aspects of the present invention consequently further the state of the technology to at least the next level.

Thus, it has been discovered that the integrated circuit system of the present invention furnishes important and heretofore unknown and unavailable solutions, capabilities, and functional aspects for improving CD control. The resulting processes and configurations are straightforward, cost-effective, uncomplicated, highly versatile and effective, can be implemented by adapting known technologies, and are thus readily suited for efficiently and economically manufacturing integrated circuit package devices.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations, which fall within the scope of the included claims. All matters hithertofore set forth herein or shown in the accompanying drawings are to be interpreted in an illustrative and non-limiting sense.

What is claimed is:

1. An integrated circuit system comprising:
providing a substrate and a material layer;
measuring a parameter of the material layer; and
correlating the thickness of an anti-reflective layer to the measured parameter of the material layer for critical dimension control.

2. The system as claimed in claim 1 wherein:
correlating the thickness of the anti-reflective layer includes feed-forward process control.

3. The system as claimed in claim 1 wherein:
measuring a parameter of the material layer includes measuring the thickness or the index of refraction of the material layer.

4. The system as claimed in claim 1 wherein:
correlating the thickness of the anti-reflective layer to the measured parameter of the material layer includes tuning the anti-reflective layer to the specific thickness of the material layer.

5. The system as claimed in claim 1 wherein:
correlating the thickness of the anti-reflective layer to the measured parameter of the material layer includes altering the light reflectivity from the material layer.

6. An integrated circuit system comprising:
providing a substrate and a material layer;
measuring a parameter of the material layer;
correlating the thickness of an anti-reflective layer to the measured parameter of the material layer for critical dimension control;
depositing the anti-reflective layer over the material layer;
depositing a photoresist material over the anti-reflective layer;
measuring a parameter of the photoresist material; and
adjusting a control parameter based upon the measured parameter of the photoresist material for critical dimension control.

7. The system as claimed in claim 6 wherein:
correlating the thickness of the anti-reflective layer to the measured parameter of the material layer includes tuning for thickness variations within the material layer.

8. The system as claimed in claim 6 wherein:
correlating the thickness of the anti-reflective layer to the measured parameter of the material layer includes feed-forward process control.

9. The system as claimed in claim 6 wherein:
adjusting the control parameter based upon the measured parameter of the photoresist material includes feedback process control.

10. The system as claimed in claim 6 further comprising:
forming a feature within the photoresist material including a critical dimension of about 65 nanometers.

11. An integrated circuit system comprising:
a substrate;
a material layer over the substrate; and
an anti-reflective layer over the material layer that is tuned to match a measured parameter of the material layer.

12. The system as claimed in claim 11 wherein:
the substrate includes a semiconducting material.

13. The system as claimed in claim 11 wherein:
the material layer includes a conducting material, a semiconducting material, a dielectric material, or a combination thereof.

14. The system as claimed in claim 11 wherein:
the material layer is on the substrate.

15. The system as claimed in claim 11 wherein:
the anti-reflective layer is tuned to match a thickness of the material layer.

16. The system as claimed in claim 11 wherein:
the anti-reflective layer is tuned to match an index of refraction of the material layer.

17. The system as claimed in claim 11 wherein:
the anti-reflective layer is on the material layer.

18. The system as claimed in claim 11 wherein:
the anti-reflective layer includes a bottom anti-reflective coating.

19. The system as claimed in claim 11 wherein:
the material layer includes a non-uniform thickness.

20. The system as claimed in claim 11 further comprising:
a photoresist material over the anti-reflective layer with a feature including a sub-65 nanometer critical dimension.
